(19) United States
(12) Patent Application Publication
(10) Pub. No.: US 2025/0003505 A1
(43) Pub. Date: Jan. 2, 2025

(54) VALVES WITH REDUCED PARTICLE GENERATION AND INCREASED CYCLE LIFE

(71) Applicant: ASML Netherlands B.V., Veldhoven (NL)

(72) Inventors: Shichen GU, San Jose, CA (US); Qingpo XI, Fremont, CA (US); Juying DOU, San Jose, CA (US)

(73) Assignee: ASML Netherlands B.V., Veldhoven (NL)

(21) Appl. No.: 18/709,792

(22) PCT Filed: Oct. 19, 2022
(86) PCT No.: PCT/EP2022/079038

§ 371 Date: May 13, 2024

Related U.S. Application Data
(60) Provisional application No. 63/279,660, filed on Nov. 15, 2021.

(51) Int. Cl. F16K 3/18; F16K 51/02

(52) U.S. Cl. CPC F16K 3/182; F16K 51/02

(57) ABSTRACT

Systems with valves that increase cycle life and reduce particle generation. Embodiments may include a first movable member, a second movable member, and a third movable member; a first link coupled to the first movable member and the second movable member such that when the second movable member is moved laterally and the third movable member is stopped, the first link exerts a force on the first movable member that causes the first movable member to move towards a surface and press against the surface to form a vacuum seal; and a second link coupled to the first movable member and the third movable member such that when the first link causes the first movable member to move, the second link exerts a force on the first movable member that limits movement of the first movable member such that the first movable member moves towards the surface with limited offset.

### CROSS-REFERENCE TO RELATED APPLICATIONS

This application claims priority of U.S. application 63/279,660 which was filed on 15 Nov. 2021 and which is incorporated herein in its entirety by reference.

### FIELD

The description herein relates to the field of valves in charged particle beam systems, and more particularly to valves that reduce particle generation and increase cycle life in systems.

### BACKGROUND

In manufacturing processes of integrated circuits (ICs), unfinished or finished circuit components are inspected to ensure that they are manufactured according to design and are free of defects. An inspection system utilizing an optical microscope typically has resolution down to a few hundred nanometers; and the resolution is limited by the wavelength of light. As the physical sizes of IC components continue to reduce down to sub-100 or even sub-10 nanometers, inspection systems capable of higher resolution than those utilizing optical microscopes are needed.

A charged particle (e.g., electron) beam microscope, such as a scanning electron microscope (SEM) or a transmission electron microscope (TEM), capable of resolution down to less than a nanometer, serves as a practicable tool for inspecting IC components having a feature size that is sub-100 nanometers. With a SEM, electrons of a single primary electron beam, or electrons of a plurality of primary electron beams, can be focused at locations of interest of a wafer under inspection. The primary electrons interact with the wafer and may be backscattered or may cause the wafer to emit secondary electrons. The intensity of the electron beams comprising the backscattered electrons and the secondary electrons may vary based on the properties of the internal and external structures of the wafer, and thereby may indicate whether the wafer has defects.

### SUMMARY

Embodiments of the present disclosure provide valves that increase cycle life and reduce particle generation in systems. In some embodiment, a valve may include a first movable member, a second movable member, and a third movable member; a first link coupled to the first movable member and the second movable member such that when the second movable member is moved laterally and the third movable member is stopped, the first link exerts a force on the first movable member that causes the first movable member to move towards a surface and press against the surface to form a vacuum seal; and a second link coupled to the first movable member and the third movable member such that when the first link causes the first movable member to move, the second link exerts a force on the first movable member that limits movement of the first movable member such that the first movable member moves towards the surface with a limited offset.

In some embodiments, an inspection system may include a chamber and a valve configured to seal the chamber to provide a vacuum environment. The valve may include a first movable member, a second movable member, and a third movable member; a first link coupled to the first movable member and the second movable member such that when the second movable member is moved laterally and the third movable member is stopped, the first link exerts a force on the first movable member that causes the first movable member to move towards a surface and press against the surface to form a vacuum seal; and a second link coupled to the first movable member and the third movable member such that when the first link causes the first movable member to move, the second link exerts a force on the first movable member that limits movement of the first movable member such that the first movable member moves towards the surface with a limited offset.

In some embodiments, a valve may include a movable member configured to receive a force that causes the movable member to move towards a surface and press against the surface to form a vacuum seal, and wherein when the movable member moves towards the surface, the movable member is configured to receive a force that limits movement of the movable member such that the movable member moves towards the surface with a limited offset.

### BRIEF DESCRIPTION OF THE DRAWINGS

FIG. 1 is a schematic diagram illustrating an exemplary electron beam inspection (EBI) system, consistent with embodiments of the present disclosure.

FIG. 2 is a schematic diagram illustrating an exemplary multi-beam system that is part of the exemplary charged particle beam inspection system of FIG. 1, consistent with embodiments of the present disclosure.

FIG. 3A illustrates a top view of an exemplary valve and FIG. 3B illustrates a cross-sectional view of the valve.

FIG. 4A illustrates an exemplary valve in an environment without a vacuum seal while FIG. 4B illustrates the exemplary valve used to seal a system and create a vacuum environment, consistent with embodiments of the present disclosure.

FIG. 5 illustrates an exemplary valve that may be used to seal a system and create a vacuum environment, consistent with embodiments of the present disclosure.

FIG. 6 illustrates an exemplary valve that may be used to seal a system and create a vacuum environment, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the subject matter recited in the appended claims. For example, although some embodiments are described in the context of utilizing electron beams, the disclosure is not so limited. Other types of charged particle beams may be similarly applied. Furthermore, other imaging systems may be used, such as optical imaging, photodetection, x-ray detection, extreme ultraviolet inspection, deep ultraviolet inspection, or the like.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection may be carried out using a scanning electron microscope (SEM). A SEM can be used to image these extremely small structures, in effect, taking a “picture” of the structures of the wafer. The image can be used to determine if the structure was formed properly and also if it was formed at the proper location. If the structure is defective, then the process can be adjusted so the defect is less likely to recur. Defects may be generated during various stages of semiconductor processing. For the reason stated above, it is important to find defects accurately and efficiently as early as possible.

The working principle of a SEM is similar to a camera. A camera takes a picture by receiving and recording brightness and colors of light reflected or emitted from people or objects. A SEM takes a “picture” by receiving and recording energies or quantities of electrons reflected or emitted from the structures. Before taking such a “picture,” an electron beam may be provided onto the structures, and when the electrons are reflected or emitted (“exiting”) from the structures, a detector of the SEM may receive and record the energies or quantities of those electrons to generate an image. To take such a “picture,” some SEMs use a single electron beam (referred to as a “single-beam SEM”), while some SEMs use multiple electron beams (referred to as a “multi-beam SEM”) to take multiple “pictures” of the wafer. By using multiple electron beams, the SEM may provide more electron beams onto the structures for obtaining these multiple “pictures,” resulting in more electrons exiting from the structures. Accordingly, the detector may receive more exiting electrons simultaneously, and generate images of the structures of the wafer with a higher efficiency and a faster speed.

An inspection system may operate in a vacuum chamber environment. When the inspection system prepares for or operates in the vacuum environment, however, water vapor, air molecules, etc. may leak into the vacuum chamber from other system components or the surrounding environment, the result of which may not be desirable for a number of reasons. One reason is that the leakage may cause the vacuum chamber to take longer to get to a predetermined vacuum pressure before inspection of a wafer may occur, thereby slowing throughput, or even preventing the vacuum chamber from being able to reach the predetermined pressure. For example, water vapor or air molecules may leak from an atmospheric environment due to inadequate sealing between the atmospheric environment and the vacuum environment. When water vapor or air molecules and the like leak into the vacuum chamber, the pressure of the vacuum chamber may increase, thereby preventing the vacuum chamber from reaching the predetermined vacuum pressure needed for inspection. This prolonged time (e.g., pump down time) for the system to reach the predetermined vacuum pressure may reduce system availability.

Additionally, water vapor, air molecules, etc. may reduce the life of the inspection system due to components being sensitive to such contaminants in the system (e.g., pure aluminum components, high voltage components, charged particle source component, etc.). Thus, the ability to prevent water vapor, air molecules and the like from entering the vacuum chamber is crucial to increasing the throughput and life of the inspection system. The type of seal between the atmospheric environment and the vacuum environment may be crucial to preventing fluids and gases from entering the vacuum environment. Valves may be used to seal systems and create a vacuum environment.

Some valve mechanisms, however, suffer from constraints. For example, contaminate particles may be generated during the operation of a valve due to friction between multiple components in motion and in contact during operation of the valve. These generated particles may contaminate other components of the system, thereby damaging the components and triggering damaging effects (e.g., high voltage arcing, etc.).

In addition to generating contaminate particles, the movement and friction between moving components of a valve also reduce the lifetime of the valve due to the resulting wear. That is, after several cycles of operation, the components of a valve may be significantly worn. For example, the contact surfaces of the components may become rougher after several cycles of operation, thereby increasing friction between contacting components. Worn out components of a valve may not only increase particle generation, but also reduce the force of a sealing component of the valve, thereby increasing leakage and degrading a vacuum seal. This leakage may further contaminate and damage components of the system.

Moreover, valves often require a skilled operator for the valve to function properly. Valves may be difficult to operate because its components are difficult to control. This results in low reproducibility and high variability in the function of a valve between different operators, resulting in inconsistent quality of the vacuum seal.

Some of the disclosed embodiments provide systems that address some or all of these disadvantages by providing valves that reduce particle generation and increase lifetime. For example, some embodiments may reduce the relative motion of components and the components may rely on clastic deformations, thereby eliminating dynamic friction and particle generation. By reducing the dynamic friction of components and reducing particle generation, the wearing-out rate of a valve may be reduced and the life cycle of a valve may be increased. In some embodiments, a valve may be operated as a single assembly such that the components of the valve may be more easily controlled. For example, a single shaft, rather than multiple components, may be adjusted to close a valve to create a vacuum seal. By operating an enhanced valve as described herein, the skill needed to operate the valve successfully is reduced, and, resultantly, the quality of the vacuum seal may be high and consistent. In some embodiments, a valve may reduce leakage and contamination of components in the system.

Relative dimensions of components in drawings may be exaggerated for clarity. Within the following description of drawings, the same or like reference numbers refer to the same or like components or entities, and only the differences with respect to the individual embodiments are described.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments.

Although the terms “left,” “right,” “horizontal,” “up,” “down,” “vertical,” etc., may be used herein to describe directions and orientations of various elements, these elements should not be limited by these terms. These terms are used to describe exemplary systems or operations of systems from exemplary perspectives. For example, a direction “up” from one perspective could be a direction “down” from another perspective, and, similarly, a direction “down” from one perspective could be a direction “up” from another perspective, without departing from the scope of the embodiments.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

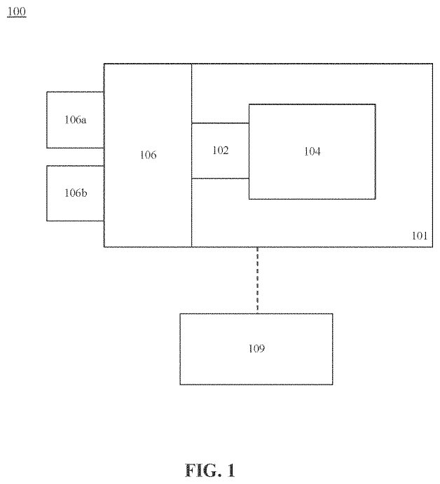

FIG. 1 illustrates an exemplary electron beam inspection (EBI) system 100 consistent with embodiments of the present disclosure. EBI system 100 may be used for imaging. As shown in FIG. 1. EBI system 100 includes a main chamber 101, a load/lock chamber 102, an electron beam tool 104, and an equipment front end module (EFEM) 106. Electron beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by electron beam tool 104. Electron beam tool 104 may be a single-beam system or a multi-beam system.

A controller 109 is electronically connected to electron beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

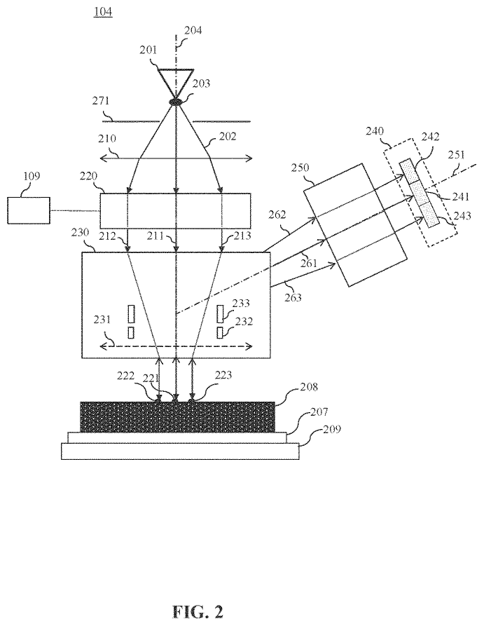

Reference is now made to FIG. 2, which is a schematic diagram illustrating an exemplary electron beam tool 104 including a multi-beam inspection tool that is part of the EBI system 100 of FIG. 1, consistent with embodiments of the present disclosure. In some embodiments, electron beam tool 104 may be operated as a single-beam inspection tool that is part of EBI system 100 of FIG. 1. Multi-beam electron beam tool 104 (also referred to herein as apparatus 104) comprises an electron source 201, a Coulomb aperture plate (or “gun aperture plate”) 271, a condenser lens 210, a source conversion unit 220, a primary projection system 230, a motorized stage 209, and a sample holder 207 supported by motorized stage 209 to hold a sample 208 (e.g., a wafer or a photomask) to be inspected. Multi-beam electron beam tool 104 may further comprise a secondary projection system 250 and an electron detection device 240. Primary projection system 230 may comprise an objective lens 231. Electron detection device 240 may comprise a plurality of detection elements 241, 242, and 243. A beam separator 233 and a deflection scanning unit 232 may be positioned inside primary projection system 230.

Electron source 201, Coulomb aperture plate 271, condenser lens 210, source conversion unit 220, beam separator 233, deflection scanning unit 232, and primary projection system 230 may be aligned with a primary optical axis 204 of apparatus 104. Secondary projection system 250 and electron detection device 240 may be aligned with a secondary optical axis 251 of apparatus 104.

Electron source 201 may comprise a cathode (not shown) and an extractor or anode (not shown), in which, during operation, electron source 201 is configured to emit primary electrons from the cathode and the primary electrons are extracted or accelerated by the extractor and/or the anode to form a primary electron beam 202 that form a primary beam crossover (virtual or real) 203. Primary electron beam 202 may be visualized as being emitted from primary beam crossover 203.

Source conversion unit 220 may comprise an image-forming element array (not shown), an aberration compensator array (not shown), a beam-limit aperture array (not shown), and a pre-bending micro-deflector array (not shown). In some embodiments, the pre-bending micro-deflector array deflects a plurality of primary beamlets 211, 212, 213 of primary electron beam 202 to normally enter the beam-limit aperture array, the image-forming element array, and an aberration compensator array. In some embodiments, apparatus 104 may be operated as a single-beam system such that a single primary beamlet is generated. In some embodiments, condenser lens 210 is designed to focus primary electron beam 202 to become a parallel beam and be normally incident onto source conversion unit 220. The image-forming element array may comprise a plurality of micro-deflectors or micro-lenses to influence the plurality of primary beamlets 211, 212, 213 of primary electron beam 202 and to form a plurality of parallel images (virtual or real) of primary beam crossover 203, one for each of the primary beamlets 211, 212, and 213. In some embodiments, the aberration compensator array may comprise a field curvature compensator array (not shown) and an astigmatism compensator array (not shown). The field curvature compensator array may comprise a plurality of micro-lenses to compensate field curvature aberrations of the primary beamlets 211, 212, and 213. The astigmatism compensator array may comprise a plurality of micro-stigmators to compensate astigmatism aberrations of the primary beamlets 211, 212, and 213. The beam-limit aperture array may be configured to limit diameters of individual primary beamlets 211, 212, and 213. FIG. 2 shows three primary beamlets 211, 212, and 213 as an example, and it is appreciated that source conversion unit 220 may be configured to form any number of primary beamlets. Controller 109 may be connected to various parts of EBI system 100 of FIG. 1, such as source conversion unit 220, electron detection device 240, primary projection system 230, or motorized stage 209. In some embodiments, as explained in further details below, controller 109 may perform various image and signal processing functions. Controller 109 may also generate various control signals to govern operations of the charged particle beam inspection system.

Condenser lens 210 is configured to focus primary electron beam 202. Condenser lens 210 may further be configured to adjust electric currents of primary beamlets 211, 212, and 213 downstream of source conversion unit 220 by varying the focusing power of condenser lens 210. Alternatively, the electric currents may be changed by altering the radial sizes of beam-limit apertures within the beam-limit aperture array corresponding to the individual primary beamlets. The electric currents may be changed by both altering the radial sizes of beam-limit apertures and the focusing power of condenser lens 210. Condenser lens 210 may be an adjustable condenser lens that may be configured so that the position of its first principal plane is movable. The adjustable condenser lens may be configured to be magnetic, which may result in off-axis beamlets 212 and 213 illuminating source conversion unit 220 with rotation angles. The rotation angles change with the focusing power or the position of the first principal plane of the adjustable condenser lens. Condenser lens 210 may be an anti-rotation condenser lens that may be configured to keep the rotation angles unchanged while the focusing power of condenser lens 210 is changed. In some embodiments, condenser lens 210 may be an adjustable anti-rotation condenser lens, in which the rotation angles do not change when its focusing power and the position of its first principal plane are varied.

Objective lens 231 may be configured to focus beamlets 211, 212, and 213 onto a sample 208 for inspection and may form, in the current embodiments, three probe spots 221, 222, and 223 on the surface of sample 208. Coulomb aperture plate 271, in operation, is configured to block off peripheral electrons of primary electron beam 202 to reduce Coulomb effect. The Coulomb effect may enlarge the size of each of probe spots 221, 222, and 223 of primary beamlets 211, 212, 213, and therefore deteriorate inspection resolution.

Beam separator 233 may, for example, be a Wien filter comprising an electrostatic deflector generating an electrostatic dipole field and a magnetic dipole field (not shown in FIG. 2). In operation, beam separator 233 may be configured to exert an electrostatic force by electrostatic dipole field on individual electrons of primary beamlets 211, 212, and 213. The electrostatic force is equal in magnitude but opposite in direction to the magnetic force exerted by magnetic dipole field of beam separator 233 on the individual electrons. Primary beamlets 211, 212, and 213 may therefore pass at least substantially straight through beam separator 233 with at least substantially zero deflection angles.

Deflection scanning unit 232, in operation, is configured to deflect primary beamlets 211, 212, and 213 to scan probe spots 221, 222, and 223 across individual scanning areas in a section of the surface of sample 208. In response to incidence of primary beamlets 211, 212, and 213 or probe spots 221, 222, and 223 on sample 208, electrons emerge from sample 208 and generate three secondary electron beams 261, 262, and 263. Each of secondary electron beams 261, 262, and 263 typically comprise secondary electrons (having electron energy ≤50 eV) and backscattered electrons (having electron energy between 50 eV and the landing energy of primary beamlets 211, 212, and 213). Beam separator 233 is configured to deflect secondary electron beams 261, 262, and 263 towards secondary projection system 250. Secondary projection system 250 subsequently focuses secondary electron beams 261, 262, and 263 onto detection elements 241, 242, and 243 of electron detection device 240. Detection elements 241, 242, and 243 are arranged to detect corresponding secondary electron beams 261, 262, and 263 and generate corresponding signals which are sent to controller 109 or a signal processing system (not shown), e.g., to construct images of the corresponding scanned areas of sample 208.

In some embodiments, detection elements 241, 242, and 243 detect corresponding secondary electron beams 261, 262, and 263, respectively, and generate corresponding intensity signal outputs (not shown) to an image processing system (e.g., controller 109). In some embodiments, each detection element 241, 242, and 243 may comprise one or more pixels. The intensity signal output of a detection element may be a sum of signals generated by all the pixels within the detection element.

In some embodiments, controller 109 may comprise image processing system that includes an image acquirer (not shown), a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detection device 240 of apparatus 104 through a medium such as an electrical conductor, optical fiber cable, portable storage media, IR, Bluetooth, internet, wireless network, wireless radio, among others, or a combination thereof. In some embodiments, the image acquirer may receive a signal from electron detection device 240 and may construct an image. The image acquirer may thus acquire images of sample 208. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, the image acquirer may acquire one or more images of a sample based on an imaging signal received from electron detection device 240. An imaging signal may correspond to a scanning operation for conducting charged particle imaging. An acquired image may be a single image comprising a plurality of imaging areas. The single image may be stored in the storage. The single image may be an original image that may be divided into a plurality of regions. Each of the regions may comprise one imaging area containing a feature of sample 208. The acquired images may comprise multiple images of a single imaging area of sample 208 sampled multiple times over a time sequence. The multiple images may be stored in the storage. In some embodiments, controller 109 may be configured to perform image processing steps with the multiple images of the same location of sample 208.

In some embodiments, controller 109 may include measurement circuitries (e.g., analog-to-digital converters) to obtain a distribution of the detected secondary electrons. The electron distribution data collected during a detection time window, in combination with corresponding scan path data of each of primary beamlets 211, 212, and 213 incident on the wafer surface, can be used to reconstruct images of the wafer structures under inspection. The reconstructed images can be used to reveal various features of the internal or external structures of sample 208, and thereby can be used to reveal any defects that may exist in the wafer.

In some embodiments, controller 109 may control motorized stage 209 to move sample 208 during inspection of sample 208. In some embodiments, controller 109 may enable motorized stage 209 to move sample 208 in a direction continuously at a constant speed. In other embodiments, controller 109 may enable motorized stage 209 to change the speed of the movement of sample 208 overtime depending on the steps of scanning process.

Although FIG. 2 shows that apparatus 104 uses three primary electron beams, it is appreciated that apparatus 104 may use two or more number of primary electron beams. The present disclosure does not limit the number of primary electron beams used in apparatus 104. In some embodiments, apparatus 104 may be a SEM used for lithography.

Compared with a single charged-particle beam imaging system (“single-beam system”), a multiple charged-particle beam imaging system (“multi-beam system”) may be designed to optimize throughput for different scan modes. Embodiments of this disclosure provide a multi-beam system with the capability of optimizing throughput for different scan modes by using beam arrays with different geometries, adapting to different throughputs and resolution requirements.

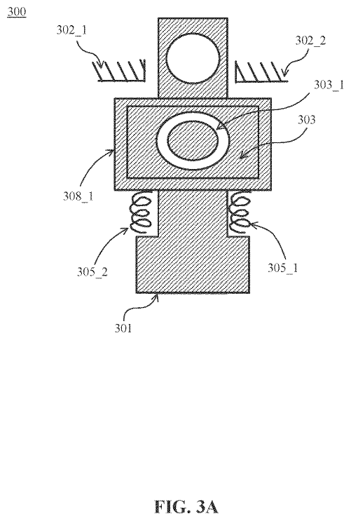

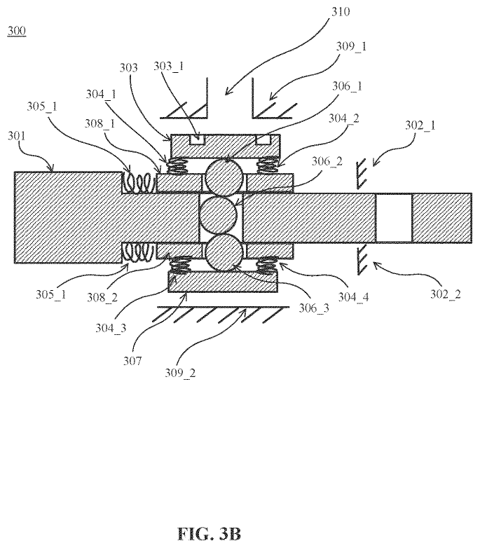

FIG. 3A illustrates a top view of an exemplary valve and FIG. 3B illustrates a cross-sectional view of the exemplary valve. A valve 300, as shown in FIGS. 3A and 3B, is often used to seal a system to create a vacuum environment.

Valve 300 may include a shaft 301 that moves from left to right to close valve 300 (e.g., to seal a system to create a vacuum environment). As shaft 301 moves from left to right, shaft 301 may push components 306_1, 306_2, and 306_3 from left to right. Components 308_1 and 308_2 may hit surface 302_1 and surface 302_2 as shaft 301 and components 306_1, 306_2, and 306_3 move from left to right. When components 308_1 and 308_2 contact surface 302, components 306_1 and 306_3 stop moving from left to right.

Shaft 301 may continue moving left to right such that shaft 301 continues to push component 306_2 left to right, thereby forcing component 306_1 to move up (e.g., in a vertical direction) and forcing component 306_3 down (e.g., in a vertical direction opposite of the direction in which component 306_1 moves). Shaft 301 may compress springs 305_1 and 305_2 as it continues to move left to right after components 308_1 and 308_2 contact surface 302. That is, component 306_2 may “squeeze” component 306_1 up and squeeze component 306_3 down when components 308_1 and 308_2 hit surfaces 302_1 and 302_2, respectively. When component 306_3 moves down, it may compress springs 304_3 and 304_4 and push component 307 down until component 307 contacts surface 309_2, at which point surface 309_2 may exert a force up on component 307, component 306_3, and component 306_2. At substantially the same time, component 306_1 moves up, compressing springs 304_1 and 304_2 and pushing component 303 up until component 303 contacts surface 309_1. When component 303 contacts surface 309_1, surface 309_1 may exert a force down on component 303, component 306_1, and component 306_2.

In some embodiments, component 303 may hold a sealing component 303_1 (e.g., an o-ring in grooves of component 303, an elastomer in component 303, etc.) that contacts surface 309_1. Component 306_2 may be held in place by a force exerted down on component 306_2 by component 306_1 and by a force exerted up on component 306_2 by component 306_2. Component 306_2 may be held in place while component 303 seals an opening 310 in surface 309_1, thereby creating a vacuum environment.

Shaft 301 may move from right to left to open valve 300 (e.g., remove the seal of component 303 and remove the vacuum environment). When shaft 301 moves left, component 306_2 may move left from springs 305_1 and 305_2 decompressing, component 306_1 may move down from springs 304_1 and 304_2 decompressing, and component 306_3 may move up from springs 304_3 and 304_4 decompressing.

Valve 300, however, suffers from constraints. For example, many particles may be generated during operation of valve 300 due to friction between multiple components in motion and in contact during operation of valve 300. These generated particles contaminate other components of a system, thereby damaging components and triggering damaging effects (e.g., high voltage arcing, etc.).

For example, particles may be generated due to friction between component 306_2 and component 306_1 and friction between 306_2 and component 306_3. Particles may also be generated due to friction between shaft 301 moving in contact with components 308_1 and 308_2; friction between shaft 301 and component 306_2; friction between component 306_1 contacting component 308_1; friction between component 306_3 contacting component 308_2; friction between component 303 contacting component 306_1; friction between component 307 contacting component 306_3; friction between springs 304_1 and 304_2 contacting component 303 and component 308_1; friction between springs 304_3 and 304_4 contacting component 307 and component 308_2; friction between spring 305_1 and component 308_1 and shaft 301; and friction between spring 305_2 and component 308_2 and shaft 301.

Moreover, while components 303 and 307 move in vertical directions (e.g., up and down), components 303 and 307 may also move in horizontal directions (e.g., left and right) while in contact with surfaces 309_1 and 309_2, thereby generating particles.

In addition to generating contaminating particles, the movement and friction between different components of valve 300 may also increase the wearing rate of valve 300. That is, after several cycles of operation, the components of valve 300 may be significantly worn out. For example, the contact surfaces of the components may become rougher after several cycles of operation, thereby increasing friction between contacting components. Worn out components of valve 300 may not only increase particle generation, but also reduce the force of component 303 on surface 309_1, thereby increasing leakage through opening 310 and breaking the vacuum seal. This leakage may further contaminate and damage components of the system.

Moreover, valve 300 often requires a skilled operator for valve 300 to function properly. Valve 300 is difficult to operate because its components (e.g., components 306_1, 306_2, and 306_3) are difficult to control. This results in low reproducibility and high variability in the function of valve 300 between different operators, resulting in inconsistent quality of the vacuum seal.

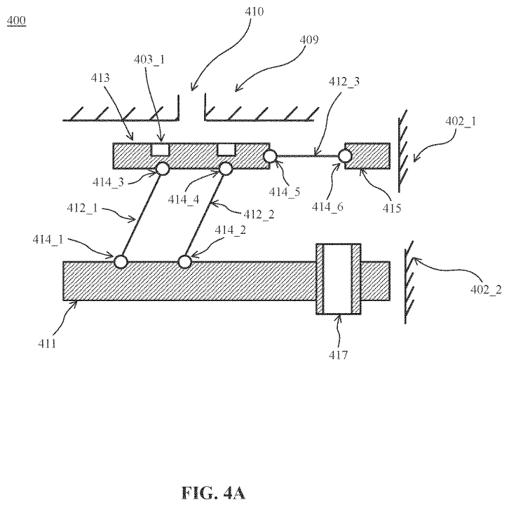

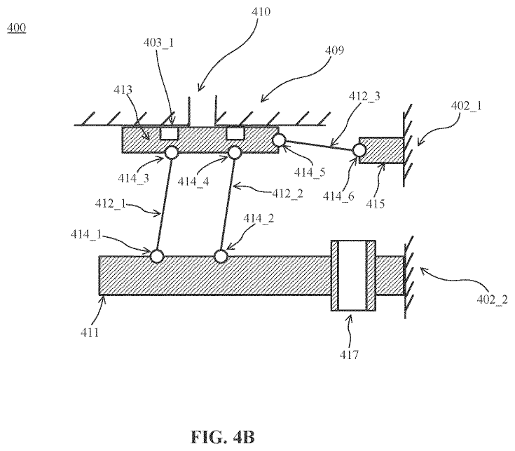

FIG. 4A illustrates an exemplary valve in an environment without a vacuum seal while FIG. 4B illustrates the exemplary valve used to seal a system and create a vacuum environment, consistent with embodiments of the present disclosure. A valve 400, as shown in FIGS. 4A and 4B, may be desirable to seal a system to create a vacuum environment.

Valve 400 may include a movable member 413, a movable member 411 (e.g., a shaft), and a movable member 415. Links 412_1 and 412_2 may be coupled to movable member 413 and movable member 411. Link 412_3 may be coupled to movable member 413 and movable member 415. Each link may include a joint at each end of the link. For example, link 412_1 may be coupled to movable member 411 by joint 414_1 and coupled to movable member 413 by joint 414_3. Link 412_2 may be coupled to movable member 411 by joint 414_2 and coupled to movable member 413 by joint 414_4. Link 412_3 may be coupled to movable member 413 by joint 414_5 and coupled to movable member 415 by joint 414_6. While only three links are depicted in FIGS. 4A and 4B, it should be understood that any number of links may couple movable member 411 to movable member 413 or couple movable member 413 to movable member 415. For example, the number of links may vary depending on the type of application or environment in which valve 400 is used.

Movable member 413 may include a sealing component 403_1 (e.g., an o-ring or an elastomer). In some embodiments, sealing component 403_1 may include an elastomer material such as natural polyisoprene, synthetic polyisoprene, polybutadiene, chloroprene, butyl rubber, styrene-butadiene rubber, nitrile rubber, ethylene propylene rubber, ethylene propylene diene rubber, propylene, epichlorohydrin rubber, polyacrylic rubber, silicone rubber, fluorosilicone rubber, fluoroelastomers (FKM and FEPM), Viton, Tecnoflon, Fluorel, Aflas, Dai-EI, perfluoroelastomers (FFKM), Tecnoflon PFR, Kalrez, Chemraz, Perlast, polyether block amides, chlorosulfonated polyethylene, Hypalon, ethylene-vinyl acetate, thermoplastic elastomers, proteins resilin and clastin, polysulfide rubber, elastolefin, poly(dichlorophosphazene), etc. In some embodiments, sealing component 403_1 may include materials with different hardness characteristics (e.g., having a durometer of 0 to 100). In some embodiments, sealing component 403_1 may include metals such as aluminum, copper, indium, gold, nickel, silver, iron, steel, titanium, chromium, zinc, scandium, vanadium, manganese, cobalt, gallium, germanium, yttrium, zirconium, niobium, molybdenum, technetium, cadmium, tin, antimony, barium, tantalum, tungsten, rhenium, osmium, iridium, platinum, lead, or their alloys.

Valve 400 may be used to create a vacuum environment by pressing movable member 413 onto surface 409 and over opening 410, thereby creating a vacuum seal. For example, movable member 411 may be moved laterally (e.g., from left to right) until movable member 415 contacts surface 402_1. Links 412_1 and 412_2 may be coupled to movable member 413 and movable member 411 such that when movable member 411 is moved to the right, movable member 415 contacts a surface 402_1 and is stopped (e.g., movable member 415 does not move, movable member 415 is stationary, etc.) before movable member 411 contacts surface 402_2. When movable member 415 is stopped, movable member 411 may continue moving right such that links 412_1 and 412_2 may each exert a force (e.g., above a threshold) on movable member 413 that causes movable member 413 to move towards surface 409 and press against surface 409 to form a vacuum seal, as shown in FIG. 4B. That is, surface 402_1 may exert a leftward force on movable member 415, which exerts a leftward force on link 412_3 and on movable member 413. The force exerted by surface 402_1 may cause links 412_1 and 412_2 to elastically deform while exerting a force on movable member 413 such that movable member 413 moves directly up toward surface 409. When links 412_1 and 412_2 elastically deform, joints 414_1, 414_2, 414_3, and 414_4 may be loaded with spring torques. In some embodiments, links 412_1 and 412_2 may be configured to limit rotation (e.g., substantially zero rotation) of movable member 413.

When movable member 415 is stopped by surface 402_1 and links 412_1 and 412_2 cause movable member 413 to move towards surface 409, surface 402_1 exerts a force on link 412_3 and link 412_3 exerts a force on movable member 413 that limits movement (e.g., lateral or horizontal movement) of movable member 413 such that movable member 413 advantageously moves up towards surface 409 with a limited (e.g., reduced, substantially zero, less than 0.2 mm, etc.) offset (e.g., lateral or horizontal movement of movable member 413). For example, a limited offset of movable member 413 may be a horizontal displacement value of zero (e.g., movable member 413 does not move in any horizontal direction). In some embodiments, a limited offset of movable member 413 may be a displacement value of zero in any direction except the vertical direction “up” (e.g., movable member 413 only moves in the vertical direction up). In some embodiments, link 412_3 may be configured to elastically deform while exerting a force on movable member 413. By exerting a force on movable member 413, link 412_3 may be configured to limit rotation of movable member 413.

In some embodiments, elastic deformation of links may occur such that there is substantially no frictional force (e.g., a frictional force of substantially zero) between components of valve 400. For example, elastic deformation of link 412_1 may occur such that there is substantially no frictional force between link 412_1 and movable member 413 and substantially no frictional force between link 412_1 and movable member 411. Elastic deformation of link 412_2 may occur such that there is substantially no frictional force between link 412_2 and movable member 413 and substantially no frictional force between link 412_2 and movable member 411. Elastic deformation of link 412_3 may occur such that there is substantially no frictional force between link 412_3 and movable member 413 and substantially no frictional force between link 412_3 and movable member 415. Elastic deformation of links 412_1, 412_2, and 412_3 may occur such that there is substantially no frictional force between movable member 413 and surface 409.

By limiting lateral offset of movable member 413 during operation of valve 400, movable member 413 may advantageously press sealing component 403_1 against surface 409 without shearing sealing component 503_1 and without creating friction between movable member 413 and surface 509. Valve 400 may advantageously eliminate failure of sealing component 403_1 and particle generation in the system.

Advantageously, valve 400 uses a mechanism that reduces relative motion of its components and where movements of the components rely on elastic deformations, thereby eliminating dynamic friction and particle generation. For example, joints 414_1, 414_2, 414_3, and 414_4 may be torsion springs and links 412_1, 412_2, and 412_3 may be made of materials that can be elastically deformed (e.g., sheets of material, metal sheets, bulk material, metal bodies, rods, metal rods, etc.). By reducing the dynamic friction of components and reducing particle generation, the wearing rate of valve 400 may be reduced and the life cycle of valve 400 may be increased. Moreover, valve 400 may be operated as a single assembly such that the components of valve 400 may be controlled, reproducibility by different operators may increase, variability between different operators may decrease, and the quality of the vacuum seal may be high and consistent. That is, valve 400 may reduce leakage and contamination of components in the system.

In some embodiments, valve 400 may be used in an inspection system (e.g., EBI system 100 of FIG. 1) where electrons or other charged particles (e.g., ions, protons, electrons, elementary particles, etc.) may travel through opening 410 when valve 400 is opened. A shield 417 (e.g., an electric shield, a magnetic shield, etc.) may be mounted on a component of valve 400 (e.g., on movable member 411). While shield 417 is depicted as being mounted on movable member 411, shield 417 may be mounted on other components of valve 400. In some embodiments, valve 400 may include a plurality of shields. In some embodiments, one or more holes may be drilled into the components (e.g., in movable member 411, in movable member 415, etc.) to provide shielding.

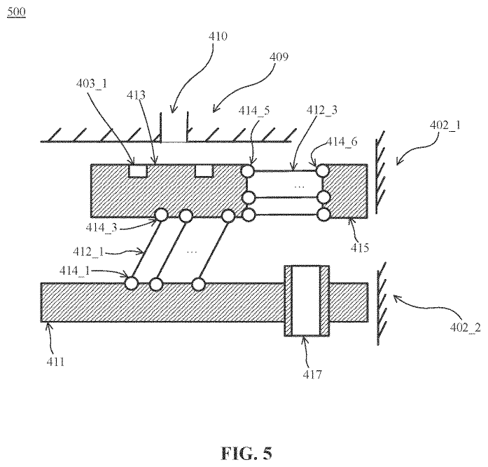

FIG. 5 illustrates an exemplary valve that may be used to seal a system and create a vacuum environment, consistent with embodiments of the present disclosure. A valve 500, as shown in FIG. 5, may be desirable to seal a system to create a vacuum environment.

It should be noted that the components of FIG. 5 operate in manner consistent with FIGS. 4A and 4B described above. FIG. 5 illustrates that valve 400 described in FIGS. 4A and 4B may be used to create a vacuum environment using any number of links while still providing the advantages described above. In some embodiments, more links may be desirable in applications where a higher force needs to be exerted to create a vacuum environment. For example, more links may be used to couple movable member 413 and movable member 411 in applications where a higher force needs to be exerted on movable member 413 to move movable member 413 vertically to surface 409 and create a vacuum environment. In some embodiments, more links may be used to couple movable member 413 with movable member 415 in applications where a higher force needs to be exerted on movable member 413 to offset lateral movement of movable member 413 while creating a vacuum environment.

In some embodiments, clastic deformation of links may occur such that there is substantially no frictional force (e.g., a frictional force of substantially zero) between components of valve 500. For example, clastic deformation of link 412_1 (e.g., one link or a plurality of links) may occur such that there is substantially no frictional force between link 412_1 and movable member 413 and substantially no frictional force between link 412_1 and movable member 411. Elastic deformation of link 412_3 (e.g., one link or a plurality of links) may occur such that there is substantially no frictional force between link 412_3 and movable member 413 and substantially no frictional force between link 412_3 and movable member 415. Elastic deformation of links 412_1 and 412_3 may occur such that there is substantially no frictional force between movable member 413 and surface 409.

In some embodiments, more links may be used to couple movable member 413 to movable member 411 or to movable member 415 to limit rotation (e.g., substantially zero rotation) of movable member 413. In some embodiments, more links may be used to couple movable member 413 to movable member 411 or to movable member 415 to provide more structural support to movable member 413 to create a vacuum environment.

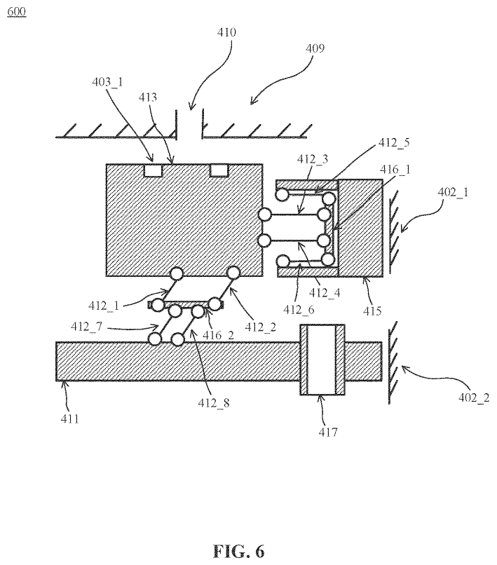

FIG. 6 illustrates an exemplary valve that may be used to seal a system and create a vacuum environment, consistent with embodiments of the present disclosure. A valve 600, as shown in FIG. 6, may be desirable to seal a system to create a vacuum environment.

It should be noted that the components of FIG. 6 operate in manner consistent with FIGS. 4A, 4B, and 5 described above. Valve 600 may be used to create a vacuum environment using any number of links while still providing the advantages described above.

Valve 600 may include a member 416_1 and links 412_3 and 412_4, which couple member 416_1 to movable member 413. Links 412_5 and 412_6 may couple member 416_1 to movable member 415 such that links 412_3 and 412_4 are coupled to movable member 415 via member 416_1. Similar to FIGS. 4A, 4B, and 5, links 412_3 and 412_4 may each be coupled to movable member 413 by a joint (e.g., a torsion spring) at one end and coupled to member 416_1 by a joint at another end. Links 412_5 and 412_6 may each be coupled to member 416_1 by a joint at one end and coupled to movable member 415 by a joint at another end.

In some embodiments, valve 600 may include a member 416_2 and links 412_7 and 412_8, which couple member 416_2 to movable member 411. Links 412_1 and 412_2 may couple member 416_2 to movable member 413 such that links 412_1 and 412_2 are coupled to movable member 411 via member 416_2. Links 412_1 and 412_2 may each be coupled to movable member 413 by a joint at one end and coupled to member 416_2 by a joint at another end.

Similar to FIGS. 4A, 4B, and 5 above, valve 600 may be used to create a vacuum environment by pressing movable member 413 onto surface 409 and over opening 410, thereby creating a vacuum seal. Movable member 411 may be moved laterally (e.g., from left to right) until movable member 415 contacts surface 402_2.

When movable member 411 is moved to the right, movable member 415 contacts a surface 402_1 and is stopped (e.g., movable member 415 does not move, movable member 415 is stationary, etc.) before movable member 411 contacts surface 402_2. When movable member 415 is stopped, movable member 411 may continue moving right such that links 412_7 and 412_8 may each exert a force on member 416_2, which in turn exerts a force on links 412_1 and 412_2. Links 412_1 and 412_2 may each exert a force on movable member 413 that causes movable member 413 to move towards surface 409 and press against surface 409 to form a vacuum seal. In some embodiments, member 416_2 may be used in applications where a higher force needs to be exerted on movable member 413 to move movable member 413 vertically to surface 409 and create a vacuum environment. In some embodiments, member 416_2 may be used to provide more structural support to movable member 413. In some embodiments, member 416_2 may include a plurality of members.

For example, surface 402_1 may exert a leftward force on movable member 415 when movable member 415 is stopped, which exerts a rightward force on links 412_5 and 412_6 and member 416_1. When movable member 415 is stopped, member 416_1 may exert a leftward force on links 412_3 and 412_4, which exert a leftward force on movable member 413. That is, the rightward force exerted on member 416_1 may be equal and opposite to the leftward force exerted on movable member 413 such that movable member 413 advantageously moves up towards surface 409 with a limited (e.g., reduced, substantially zero, less than 0.2 mm, etc.) offset (e.g., lateral or horizontal movement of movable member 413). The force exerted by surface 402_1 may cause links 412_5 and 412_6 to elastically deform while exerting a force on member 416_1 such that movable member 413 moves directly up toward surface 409. The force exerted by member 416_1 may cause links 412_3 and 412_4 to elastically deform while exerting a force on movable member 413 such that movable member 413 moves directly up toward surface 409. When links 412_3, 412_4, 412_5, and 412_6 elastically deform, the joints on each link may be loaded with spring torques. In some embodiments, links 412_3, 412_4, 412_5, and 412_6 may be configured to limit rotation of movable member 413.

In some embodiments, elastic deformation of links may occur such that there is substantially no frictional force (e.g., a frictional force of substantially zero) between components of valve 600. For example, elastic deformation of link 412_1 may occur such that there is substantially no frictional force between link 412_1 and movable member 413 and substantially no frictional force between link 412_1 and member 416_2. Elastic deformation of link 412_2 may occur such that there is substantially no frictional force between link 412_2 and movable member 413 and substantially no frictional force between link 412_2 and member 416_2. Elastic deformation of link 412_7 may occur such that there is substantially no frictional force between link 412_7 and member 416_2 and substantially no frictional force between link 412_7 and movable member 411. Elastic deformation of link 412_8 may occur such that there is substantially no frictional force between link 412_8 and member 416_2 and substantially no frictional force between link 412_8 and movable member 411. Elastic deformation of link 412_3 may occur such that there is substantially no frictional force between link 412_3 and movable member 413 and substantially no frictional force between link 412_3 and member 416_1. Elastic deformation of link 412_4 may occur such that there is substantially no frictional force between link 412_4 and movable member 413 and substantially no frictional force between link 412_4 and member 416_1. Elastic deformation of link 412_5 may occur such that there is substantially no frictional force between link 412_5 and member 416_1 and substantially no frictional force between link 412_5 and movable member 415. Elastic deformation of link 412_6 may occur such that there is substantially no frictional force between link 412_6 and member 416_1 and substantially no frictional force between link 412_6 and movable member 415. Elastic deformation of links 412_1, 412_2, 412_3, 412_4, 412_5, 412_6, 412_7, and 412_8 may occur such that there is substantially no frictional force between movable member 413 and surface 409.

In some embodiments, member 416_1 may be used in applications where a higher force needs to be exerted on movable member 413 to offset lateral movement of movable member 413 while creating a vacuum environment. In some embodiments, member 416_1 may include a plurality of members.

By limiting the lateral offset of movable member 413 during operation of valve 600, movable member 413 may advantageously press sealing component 403_1 against surface 409 without shearing sealing component 403_1 and without creating friction between movable member 413 and surface 409. Valve 600 may advantageously eliminate failure of sealing component 403_1 and particle generation in the system.

While FIG. 6 depicts both member 416_1 and member 416_2, some embodiments may only include member 416_1 while some embodiments may only include 416_2. For example, some embodiments may include member 416_1, but not member 416_2, such that movable member 413 and movable member 411 are only coupled by one or more links. Some embodiments may include member 416_2, but not member 416_1, such that movable member 413 and movable member 415 are only coupled by one or more links.

The embodiments may further be described using the following clauses:

1. A valve comprising:
a first movable member, a second movable member, and a third movable member;
a first link coupled to the first movable member and the second movable member such that when the second movable member is moved laterally and the third movable member is stopped, the first link exerts a force on the first movable member that causes the first movable member to move towards a surface and press against the surface to form a vacuum seal; and
a second link coupled to the first movable member and the third movable member such that when the first link causes the first movable member to move, the second link exerts a force on the first movable member that limits movement of the first movable member such that the first movable member moves towards the surface with a limited offset.
   2. The valve of clause 1, wherein the third movable member is stopped when the third movable member does not move.
   3. The valve of any one of clauses 1-2, wherein the third movable member is stopped when the third movable member is stationary.
   4. The valve of any one of clauses 1-3, wherein the limited offset is less than 0.2 mm.
   5. The valve of any one of clauses 1-4, wherein the limited offset is substantially zero.
   6. The valve of any one of clauses 1-5, wherein the first link is configured to elastically deform while exerting a force on the first movable member.
   7. The valve of clause 6, wherein the elastic deformation occurs such that there is substantially no frictional force between the first movable member and the first link.
   8. The valve of any one of clauses 6-7, wherein the elastic deformation occurs such that there is substantially no frictional force between the first link and second movable member.
   9. The valve of any one of clauses 1-8, wherein the first link is configured to limit rotation of the first movable member.
   10. The valve of clause 9, wherein the limited rotation is substantially zero.
   11. The valve of any one of clauses 1-10, wherein the first link is part of a plurality of links coupled to the first movable member and the second movable member.
   12. The valve of any one of clauses 1-11, wherein the second link is configured to elastically deform while exerting a force on the first movable member.
   13. The valve of clause 12, wherein the elastic deformation occurs such that there is substantially no frictional force between the second link and first movable member.
   14. The valve of any one of clauses 12-13, wherein the elastic deformation occurs such that there is substantially no frictional force between the second link and third movable member.
   15. The valve of any one of clauses 12-14, wherein the elastic deformation occurs such that there is substantially no frictional force between the first movable member and the surface.
   16. The valve of any one of clauses 1-15, wherein the second link is configured to limit rotation of the first movable member.
   17. The valve of any one of clauses 1-16, wherein the second link is part of a plurality of links coupled to the first movable member and the third movable member.
   18. The valve of any one of clauses 1-17, further comprising a shield on any one of the first movable member, the second movable member, or the third movable member.
   19. The valve of clause 18, wherein the shield comprises any one of a magnetic shield or an electric shield.
   20. The valve of any one of clauses 1-19, wherein the first movable member comprises a sealing component.
   21. The valve of any one of clauses 1-20, further comprising a fourth member and a third link coupled to the third movable member and the fourth member, wherein:
the second link is coupled to the third movable member via the fourth member, the second link being coupled to the first movable member and the fourth member, and
the third link being configured to exert a force on the fourth member in a direction opposite to the force exerted on the first movable member by the second link such that the first movable member moves towards the surface with a limited offset.
   22. The valve of any one of clauses 1-21, further comprising a fifth member and a fourth link coupled to the second movable member and the fifth member, wherein:
the first link is coupled to the second movable member via the fifth member, and
the fourth link being configured to exert a force on the fifth member that causes the fifth member to exert a force on the first link.
   23. An inspection system comprising:
a chamber;
a valve configured to seal the chamber to provide a vacuum environment, the valve comprising:
a first movable member, a second movable member, and a third movable member;
a first link coupled to the first movable member and the second movable member such that when the second movable member is moved laterally and the third movable member is stopped, the first link exerts a force on the first movable member that causes the first movable member to move towards a surface and press against the surface to form a vacuum seal; and
a second link coupled to the first movable member and the third movable member such that when the first link causes the first movable member to move, the second link exerts a force on the first movable member that limits movement of the first movable member such that the first movable member moves towards the surface with a limited offset.
   24. The inspection system of clause 23, wherein the third movable member is stopped when the third movable member does not move.
   25. The inspection system of any one of clauses 23-24, wherein the third movable member is stopped when the third movable member is stationary.
   26. The inspection system of any one of clauses 23-25, wherein the limited offset is less than 0.2 mm.
   27. The inspection system of any one of clauses 23-26, wherein the limited offset is substantially zero.
   28. The inspection system of any one of clauses 23-27, wherein the first link is configured to elastically deform while exerting a force on the first movable member.
   29. The inspection system of clause 28, wherein the elastic deformation occurs such that there is substantially no frictional force between the first movable member and the first link.
   30. The inspection system of any one of clauses 28-29, wherein the elastic deformation occurs such that there is substantially no frictional force between the first link and second movable member.
   31. The inspection system of any one of clauses 23-30, wherein the first link is configured to limit rotation of the first movable member.
   32. The inspection system of clause 31, wherein the limited rotation is substantially zero.
   33. The inspection system of any one of clauses 23-32, wherein the first link is part of a plurality of links coupled to the first movable member and the second movable member.
   34. The inspection system of any one of clauses 23-33, wherein the second link is configured to elastically deform while exerting a force on the first movable member.
   35. The inspection system of clause 34, wherein the elastic deformation occurs such that there is substantially no frictional force between the second link and first movable member.
   36. The inspection system of any one of clauses 34-35, wherein the elastic deformation occurs such that there is substantially no frictional force between the second link and third movable member.
   37. The inspection system of any one of clauses 34-36, wherein the elastic deformation occurs such that there is substantially no frictional force between the first movable member and the surface.
   38. The inspection system of any one of clauses 23-37, wherein the second link is configured to limit rotation of the first movable member.
   39. The inspection system of any one of clauses 23-38, wherein the second link is part of a plurality of links coupled to the first movable member and the third movable member.
   40. The inspection system of any one of clauses 23-39, further comprising a shield on any one of the first movable member, the second movable member, or the third movable member.
   41. The inspection system of clause 40, wherein the shield comprises any one of a magnetic shield or an electric shield.
   42. The inspection system of any one of clauses 23-41, wherein the first movable member comprises a sealing component.
   43. The inspection system of any one of clauses 23-42, further comprising a fourth member and a third link coupled to the third movable member and the fourth member, wherein:
the second link is coupled to the third movable member via the fourth member, the second link being coupled to the first movable member and the fourth member, and
the third link being configured to exert a force on the fourth member in a direction opposite to the force exerted on the first movable member by the second link such that the first movable member moves towards the surface with a limited offset.
   44. The inspection system of any one of clauses 23-43, further comprising a fifth member and a fourth link coupled to the second movable member and the fifth member, wherein:
the first link is coupled to the second movable member via the fifth member, and
the fourth link being configured to exert a force on the fifth member that causes the fifth member to exert a force on the first link.
   45. A valve comprising:
a movable member configured to receive a force that causes the movable member to move towards a surface and press against the surface to form a vacuum seal, and
wherein when the movable member moves towards the surface, the movable member is configured to receive a force that limits movement of the movable member such that the movable member moves towards the surface with a limited offset.
   46. The valve of clause 45, wherein the movable member is configured to receive the force that causes the movable member to move towards the surface and press against the surface to form the vacuum seal from a first link.
   47. The valve of any one of clauses 45-46, wherein the movable member is a first movable member and the first link is coupled to the first movable member and a second movable member, such that when the second movable member is moved laterally and a third movable member is stopped, the first link exerts the force on the first movable member that causes the first movable member to move towards the surface and press against the surface to form the vacuum seal.
   48. The valve of any one of clauses 45-47, wherein the movable member is configured to receive the force that limits movement of the movable member such that the movable member moves towards the surface with the limited offset from a second link.
   49. The valve of any one of clauses 45-48, wherein the movable member is a first movable member and a second link is coupled to the first movable member and a third movable member, such that when a first link causes the first movable member to move the second link exerts a force on the first movable member that limits movement of the first movable member such that the first movable member moves towards the surface with the limited offset.
   50. The valve of any one of clauses 47-49, wherein the third movable member is configured to stop when the third movable member does not move.
   51. The valve of any one of clauses 47-50, wherein the third movable member is configured to stop when the third movable member is stationary.
   52. The valve of any one of clauses 45-51, wherein the limited offset is less than 0.2 mm.
   53. The valve of any one of clauses 45-52, wherein the limited offset is substantially zero.
   54. The valve of any one of clauses 47-53, wherein the first link is configured to elastically deform while exerting a force on the first movable member.
   55. The valve of clause 54, wherein the elastic deformation occurs such that there is substantially no frictional force between the first movable member and the first link.
   56. The valve of any one of clauses 54-55, wherein the elastic deformation occurs such that there is substantially no frictional force between the first link and second movable member.
   57. The valve of any one of clauses 47-56, wherein the first link is configured to limit rotation of the first movable member.
   58. The valve of clause 57, wherein the limited rotation is substantially zero.
   59. The valve of any one of clauses 47-58, wherein the first link is part of a plurality of links coupled to the first movable member and the second movable member.
   60. The valve of any one of clauses 48-59, wherein the second link is configured to elastically deform while exerting a force on the first movable member.
   61. The valve of clause 60, wherein the elastic deformation occurs such that there is substantially no frictional force between the second link and first movable member.
   62. The valve of any one of clauses 60-61, wherein the elastic deformation occurs such that there is substantially no frictional force between the second link and third movable member.
   63. The valve of any one of clauses 60-62, wherein the elastic deformation occurs such that there is substantially no frictional force between the first movable member and the surface.
   64. The valve of any one of clauses 48-63, wherein the second link is configured to limit rotation of the first movable member.
   65. The valve of any one of clauses 48-64, wherein the second link is part of a plurality of links coupled to the first movable member and the third movable member.
   66. The valve of any one of clauses 47-65, further comprising a shield on any one of the first movable member, the second movable member, or the third movable member.
   67. The valve of clause 66, wherein the shield comprises any one of a magnetic shield or an electric shield.
   68. The valve of any one of clauses 47-67, wherein the first movable member comprises a sealing component.
   69. The valve of any one of clauses 48-68, further comprising a fourth member and a third link coupled to the third movable member and the fourth member, wherein:
the second link is coupled to the third movable member via the fourth member, the second link being coupled to the first movable member and the fourth member, and
the third link being configured to exert a force on the fourth member in a direction opposite to the force exerted on the first movable member by the second link such that the first movable member moves towards the surface with a limited offset.
   70. The valve of any one of clauses 48-69, further comprising a fifth member and a fourth link coupled to the second movable member and the fifth member, wherein:
the first link is coupled to the second movable member via the fifth member, and
the fourth link being configured to exert a force on the fifth member that causes the fifth member to exert a force on the first link.

It will be appreciated that the embodiments of the present disclosure are not limited to the exact construction that has been described above and illustrated in the accompanying drawings, and that various modifications and changes may be made without departing from the scope thereof.

1. An inspection system comprising:
a chamber;
a valve configured to seal the chamber to provide a vacuum environment, the valve comprising:
a first movable member, a second movable member, and a third movable member;
a first link coupled to the first movable member and the second movable member such that when the second movable member is moved laterally and the third movable member is stopped, the first link exerts a force on the first movable member that causes the first movable member to move towards a surface and press against the surface to form a vacuum seal; and
a second link coupled to the first movable member and the third movable member such that when the first link causes the first movable member to move, the second link exerts a force on the first movable member that limits movement of the first movable member such that the first movable member moves towards the surface with a limited offset.

2. The inspection system of claim 1, wherein the third movable member is stopped when the third movable member does not move.

3. The inspection system of claim 1, wherein the limited offset is less than 0.2 mm.

4. The inspection system of claim 1, wherein the first link is configured to elastically deform while exerting a force on the first movable member.

5. The inspection system of claim 4, wherein the elastic deformation occurs such that there is substantially no frictional force between the first movable member and the first link.

6. The inspection system of claim 4, wherein the elastic deformation occurs such that there is substantially no frictional force between the first link and second movable member.

7. The inspection system of claim 1, wherein the first link is configured to limit rotation of the first movable member.

8. The inspection system of claim 1, wherein the second link is configured to elastically deform while exerting a force on the first movable member.

9. The inspection system of claim 8, wherein the elastic deformation occurs such that there is substantially no frictional force between the second link and first movable member.

10. The inspection system of claim 8, wherein the elastic deformation occurs such that there is substantially no frictional force between the second link and third movable member.

11. The inspection system of claim 8, wherein the elastic deformation occurs such that there is substantially no frictional force between the first movable member and the surface.

12. The inspection system of claim 1, wherein the second link is configured to limit rotation of the first movable member.

13. The inspection system of claim 1, further comprising a shield on any one of the first movable member, the second movable member, or the third movable member.

14. The inspection system of claim 1, wherein the first movable member comprises a sealing component.

15. A valve comprising:
a first movable member, a second movable member, and a third movable member;
a first link coupled to the first movable member and the second movable member such that when the second movable member is moved laterally and the third movable member is stopped, the first link exerts a force on the first movable member that causes the first movable member to move towards a surface and press against the surface to form a vacuum seal; and
a second link coupled to the first movable member and the third movable member such that when the first link causes the first movable member to move, the second link exerts a force on the first movable member that limits movement of the first movable member such that the first movable member moves towards the surface with a limited offset.

16. A valve comprising:
a movable member configured to receive a force that causes the movable member to move towards a surface and press against the surface to form a vacuum seal, and
wherein when the movable member moves towards the surface, the movable member is configured to receive a force that limits movement of the movable member such that the movable member moves towards the surface with a limited offset.

17. The valve of claim 16, wherein the movable member is configured to receive the force that causes the movable member to move towards the surface and press against the surface to form the vacuum seal from a first link.

18. The valve of claim 16, wherein the movable member is a first movable member and the first link is coupled to the first movable member and a second movable member, such that when the second movable member is moved laterally and a third movable member is stopped, the first link exerts the force on the first movable member that causes the first movable member to move towards the surface and press against the surface to form the vacuum seal.

19. The valve of claim 16, wherein the movable member is configured to receive the force that limits movement of the movable member such that the movable member moves towards the surface with the limited offset from a second link.

20. The valve of claim 16, wherein the movable member is a first movable member and a second link is coupled to the first movable member and a third movable member, such that when a first link causes the first movable member to move the second link exerts a force on the first movable member that limits movement of the first movable member such that the first movable member moves towards the surface with the limited offset.
